(19) United States
(12) Patent Application Publication
(10) Pub. No.: US 2026/0013386 A1
(43) Pub. Date: Jan. 8, 2026

(54) DEPOSITION APPARATUS AND INSPECTION METHOD

(71) Applicant: Samsung Display Co., LTD., Yongin-si (KR)

(72) Inventors: Chang Wook SEO, Yongin-si (KR); Eu Gene KANG, Yongin-si (KR); Byung Hun SUNG, Yongin-si (KR); Dae Young OH, Yongin-si (KR); Seung Geun YUN, Yongin-si (KR); Sang Keun LEE, Yongin-si (KR); Sung Yong LEE, Yongin-si (KR); Yong Woo JEONG, Yongin-si (KR)

(21) Appl. No.: 19/170,487

(22) Filed: Apr. 4, 2025

(30) Foreign Application Priority Data
Jul. 2, 2024 (KR) 10-2024-0086524

(51) Int. Cl. H10K 71/16; H01L 21/683

(52) U.S. Cl. CPC H10K 71/164; H01L 21/6831

(57) ABSTRACT

A deposition apparatus includes an electrostatic chuck which supports a substrate, a mask assembly disposed on a surface of the substrate, a deposition module disposed to be movable in a horizontal direction intersecting a thickness direction of the mask assembly, where the deposition module discharges a deposition material to the mask assembly, and a camera which captures an image of the electrostatic chuck or the mask assembly, where the deposition module is in a deposition position overlapping the mask assembly in the thickness direction of the mask assembly while the deposition module discharges the deposition material, and is in a standby position not overlapping the mask assembly in the thickness direction of the mask assembly while the deposition module does not discharge the deposition material, and the camera captures the image of the electrostatic chuck or the mask assembly when the deposition module is in the standby position.

This application claims priority to Korean Patent Application No. 10-2024-0086524, filed on Jul. 2, 2024, and all the benefits accruing therefrom under 35 U.S.C. § 119, the content of which in its entirety is herein incorporated by reference.

### BACKGROUND

### 1. Field

Embodiments of the disclosure relate to a deposition apparatus and a method of inspecting the deposition apparatus.

### 2. Description of the Related Art

An organic light-emitting display device utilizes the phenomenon that electrons injected from a cathode and holes injected from an anode recombine in an organic thin film to form excitons, and light of a particular wavelength is generated as energy is released when the excitons relax from an excited state to the ground state.

In a manufacturing process of an organic light-emitting display device, vacuum deposition using a deposition apparatus may be used as a method for depositing an organic material or metal used as electrodes. The vacuum deposition may be carried out by placing a substrate on which an organic thin film is to be deposited on an electrostatic chuck placed inside a vacuum chamber, bring a mask assembly having a same pattern as the pattern of the thin film to be formed into contact with the substrate, and then evaporating or sublimating a deposition material such as an organic material using a deposition module to deposit the organic material on the substrate.

### SUMMARY

In a manufacturing process of an organic light-emitting display device, if particles exist on a surface of an electrostatic chuck or a mask assembly is not located at the right position during a process of depositing a deposition material, a defect may occur in the organic light-emitting display device.

Embodiments of the disclosure provide a deposition apparatus that can inspect whether an electrostatic chuck and a mask assembly inside a chamber is normal or not, and an inspection method by the deposition apparatus.

However, embodiments of the disclosure are not restricted to those set forth herein. The above and other embodiments of the disclosure will become more apparent to one of ordinary skill in the art to which the disclosure pertains by referencing the detailed description of the disclosure given below.

According to an embodiment of the disclosure, a deposition apparatus includes an electrostatic chuck which supports a substrate, a mask assembly disposed on a surface of the substrate, a deposition module disposed to be movable in a horizontal direction intersecting a thickness direction of the mask assembly, where the deposition module discharges a deposition material to the mask assembly, and a camera which captures an image of the electrostatic chuck or the mask assembly, where the deposition module is in a deposition position overlapping the mask assembly in the thickness direction of the mask assembly while the deposition module discharges the deposition material, and is in a standby position not overlapping the mask assembly in the thickness direction of the mask assembly while the deposition module does not discharge the deposition material, and where the camera captures the image of the electrostatic chuck or the mask assembly when the deposition module is in the standby position.

In an embodiment, the camera may overlap the deposition module in the thickness direction of the mask assembly when the deposition module is in the deposition position, and may not overlap the deposition module in the thickness direction of the mask assembly when the deposition module is in the standby position.

In an embodiment, the camera under the deposition module may be disposed below the mask assembly to overlap the mask assembly in the thickness direction.

In an embodiment, the deposition apparatus may further include a chamber which accommodates the electrostatic chuck, the mask assembly, the deposition module and the camera, and a connection module disposed inside the chamber, where the connection module connects an outside of the chamber with an inside of the deposition module.

In an embodiment, the camera may be disposed inside the connection module.

In an embodiment, the connection module may include a first fixing member disposed on an inner surface of the chamber located below the mask assembly, where the first fixing member provides a passage with the outside of the chamber, a first rotating member with one end rotatably connected to the first fixing member, where a first communication space is defined in the first rotating member to communicate with the outside of the chamber, a second fixing member disposed on the deposition module, where the second fixing member provides a passage with the inside of the deposition module, and a second rotating member with one end rotatably connected to an opposite end of the first rotating member and an opposite end rotatably connected to the second fixing member, where a second communication space is defined in the second rotating member to communicate with the first communication space and the inside of the deposition module.

In an embodiment, the connection module may further include a rotating connection member which rotatably connects the opposite end of the first rotating member with the one end of the second rotating member.

In an embodiment, the camera may be disposed inside the one end of the first rotating member.

In an embodiment, the camera may be disposed in a way such that a lens thereof faces the mask assembly, and an observation window may be disposed on an upper side of the one end of the first rotating member.

In an embodiment, the deposition module may include a rail extending in the horizontal direction; a main body disposed to be movable along the rail; and a deposition nozzle disposed on the main body to discharge the deposition material to the mask assembly.

In an embodiment, the deposition apparatus may further include an analysis unit which analyzes the image captured by the camera to determine whether the electrostatic chuck or the mask assembly is normal or not.

According to an embodiment of the disclosure, an inspection method for a deposition apparatus includes moving a deposition module to a standby position, firstly capturing, by a camera, an image of an electrostatic chuck, placing a mask assembly under the electrostatic chuck, and firstly capturing, by the camera, an image of the mask assembly.

In an embodiment, the deposition module may not overlap the electrostatic chuck or the mask assembly in a thickness direction of the electrostatic chuck or the mask assembly when the deposition module is in the standby position.

In an embodiment, the camera may be disposed below the electrostatic chuck or the mask assembly to overlap the electrostatic chuck or the mask assembly.

In an embodiment, the inspection method may further include after the firstly capturing, by the camera, the image of the mask assembly, placing a substrate on the electrostatic chuck.

In an embodiment, the inspection method may further include after the placing the substrate on the electrostatic chuck, moving the deposition module to a deposition position and discharging a deposition material to the mask assembly.

In an embodiment, the deposition module may overlap the electrostatic chuck or the mask assembly in a thickness direction of the electrostatic chuck or the mask assembly when the deposition module is in the deposition position.

In an embodiment, the inspection method may further include after the discharging a deposition material to the mask assembly, moving the deposition module to the standby position.

In an embodiment, the inspection method may further include after the moving the deposition module to the standby position, unloading the substrate from the electrostatic chuck, and secondly capturing, by the camera, an image of the mask assembly.

In an embodiment, the inspection method may further include after the capturing, by the camera, the image of the mask assembly, unloading the mask assembly, and secondly capturing, by the camera, an image of the electrostatic chuck.

According to an embodiment of the disclosure, it is possible to inspect, by a deposition apparatus, whether an electrostatic chuck and a mask assembly inside a chamber is normal or not, thereby effectively preventing failure in a process of depositing a deposition material onto a substrate.

The effects according to the embodiments of the disclosure are not limited to those mentioned above and more various effects are included in the following description of the disclosure.

### BRIEF DESCRIPTION OF THE DRAWINGS

The above and other features of embodiments of the disclosure will become more apparent by describing in detail embodiments thereof with reference to the accompanying drawings, in which:

FIG. 1 is a view showing a deposition apparatus according to an embodiment of the disclosure;

FIG. 2 is a cross-sectional view taken along line A-A′ of FIG. 1;

FIG. 3 is a view showing the deposition module and the connection module of FIG. 1;

FIG. 4 is a view showing the connection module of FIG. 1;

FIG. 5 is a flowchart for illustrating a method of inspecting by a deposition apparatus according to an embodiment of the disclosure;

FIG. 6 is a view showing the first deposition standby process and the firstly inspecting an electrostatic chuck of FIG. 5;

FIG. 7 is a view showing the pacing a mask assembly and the firstly inspecting the mask assembly of FIG. 5;

FIG. 8 is a view showing the placing the substrate of FIG. 5;

FIG. 9 is a view showing the deposition process of FIG. 5;

FIG. 10 is a view showing the second deposition standby process of FIG. 5;

FIG. 11 is a view showing the unloading the substrate and the secondly inspecting the mask assembly of FIG. 5; and

FIG. 12 is a view showing the unloading the mask assembly and the secondly inspecting the electrostatic chuck of FIG. 5.

FIG. 13 is a block diagram of an electronic device according to one embodiment of the present disclosure.

FIG. 14 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

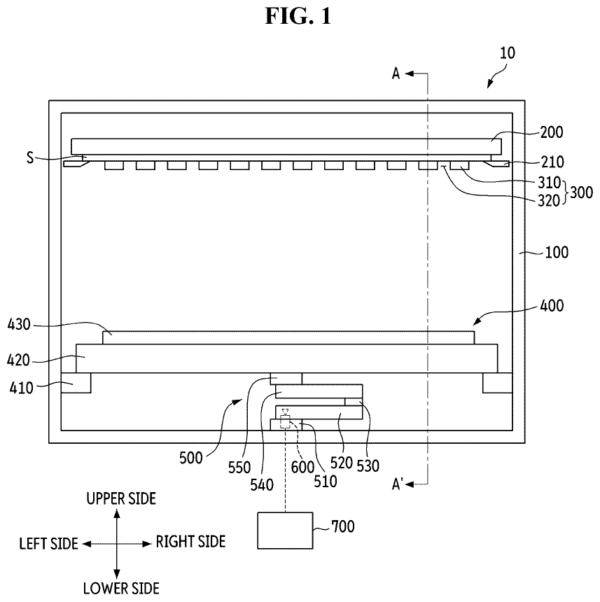

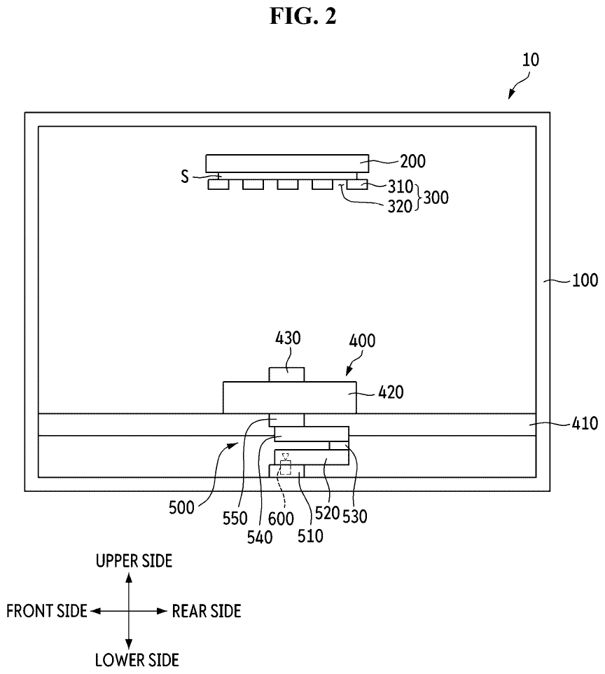

FIG. 1 is a view showing a deposition apparatus 10 according to an embodiment of the disclosure. FIG. 2 is a cross-sectional view taken along the line A-A′ of FIG. 1.

Referring to FIGS. 1 and 2, a deposition apparatus 10 according to an embodiment of the disclosure may deposit an organic material or a metal used as an electrode on a substrate S. In an embodiment, the deposition device 10 may include a chamber 100, an electrostatic chuck 200, a substrate holder 210, a mask assembly 300, a deposition module 400, a connection module 500, a camera 600, and an analysis unit 700.

The chamber 100 may provide or define a space for performing a deposition process. The inside (or an inner space) of the chamber 100 may be maintained under vacuum while performing the deposition process. Maintaining the inside of the chamber 100 under vacuum may mean maintaining the pressure inside the chamber 100 at a low pressure, which is a pressure lower than a predetermined pressure. The chamber 100 may include an inlet/outlet (not shown) for loading/unloading a substrate S. In addition, the chamber 100 may include a vacuum pump (not shown) for controlling the pressure inside the chamber 100 and discharging a deposition material that is not deposited on the substrate S, and an exhaust port (not shown) connected to the vacuum pump. The chamber 100 may accommodate at least one selected from the electrostatic chuck 200, the substrate holder 210, the mask assembly 300, the deposition module 400, the connection module 500, the camera 600 and the analysis unit 700.

The substrate S on which the organic material or metal used as the electrode is deposited may be provided as an insulating substrate, a semiconductor substrate, a display device substrate, etc., but the disclosure is not limited thereto. According to an embodiment, the substrate S may be a substrate used in an organic light-emitting display device, for example. A predetermined structure may be formed on the substrate S via a deposition process. Depending on the fabrication process of the organic light-emitting display device, the structure formed on the substrate S via the deposition process can be formed in various ways. For example, in a process of forming a hole injection layer, a pixel-defining film and an anode electrode may be formed on the substrate S. In addition, in a process of forming an organic light-emitting layer, not only a pixel-defining layer and an anode electrode, but also a hole injection layer and a hole transport layer may be formed on the substrate S.

The electrostatic chuck 200 may support the substrate S. The electrostatic chuck 200 may be disposed inside the chamber 100. According to an embodiment of the disclosure, the electrostatic chuck 200 may be disposed on the upper side (or an upper portion of the inner space) in the chamber 100, and the substrate S may be seated under the electrostatic chuck 200 and supported by the electrostatic chuck 200. The electrostatic chuck 200 may chuck or dechuck the substrate S by electrostatic force. The electrostatic chuck 200 may be a bipolar type or a monopolar type. A bipolar-type electrostatic chuck 200 may include two electrode plates, and the substrate S may be chucked when a voltage is applied between the two electrode plates. A monopolar-type electrostatic chuck 200 may include only one electrode plate, and the substrate S may be chucked when a voltage is applied between the electrode plate and the substrate S. The electrostatic chuck 200 may dechuck the substrate S after the deposition process has been performed. In an embodiment, the electrostatic chuck 200 may include a fixing member. The fixing member may assist in fixing the substrate S and the mask assembly 300, and may maintain a constant distance between the substrate S and the mask assembly 300. The fixing member may have a detachable frame structure.

The substrate holder 210 may be disposed between the electrostatic chuck 200 and the mask assembly 300. There may be a plurality of substrate holders 210, that is, the substrate holder 210 may be provided in plural, and the plurality of substrate holders 210 may hold the substrate S.

The mask assembly 300 may define a region where a deposition material discharged from the deposition module 400 is to be deposited on the substrate S. The mask assembly 300 may be disposed under the substrate. The mask assembly 300 may include mask portions 310, transmissive portions 320, and mask sidewalls (not shown). The mask portions 310 may cover some regions of the substrate S to prevent the deposition material discharged from the deposition module 400 from being deposited at those regions. The transmissive portions 320 may be open regions formed between the mask portions 310 that expose some regions of the substrate S. The deposition material may be sprayed onto the exposed regions of the substrate S exposed by the transmissive portions 320, such that the deposition material may be deposited on the exposed regions of the substrate S. The deposition material sprayed from the deposition module 400 may form a predetermined pattern through the mask assembly 300 and may be deposited on the substrate S. The mask sidewalls may be located in the edges of the mask assembly 300 to effectively prevent the deposition material from spreading to areas other than the substrate S. The mask assembly 300 may be a mother glass mask such as a fine metal mask (FMM) or may include a plurality of segmented masks, but the disclosure is not limited thereto. The mask assembly 300 may be fixed closely to the substrate S, and the gap between the mask assembly 300 and the substrate S may be adjusted by the electrostatic chuck 200 and the fixing member.

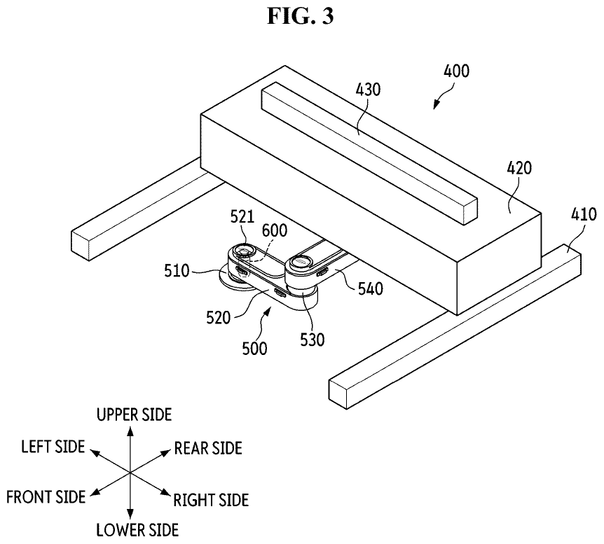

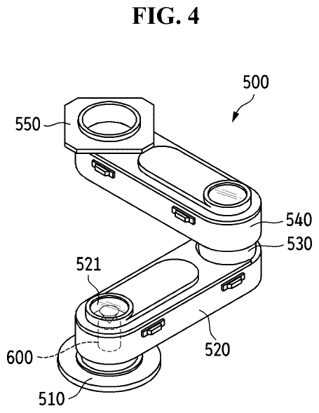

FIG. 3 is a view showing the deposition module 400 and the connection module 500 of FIG. 1. FIG. 4 is a view showing the connection module 500 of FIG. 1.

Referring to FIGS. 3 and 4, an embodiment of the deposition module 400 may discharge a deposition material to be deposited on the substrate S. The deposition module 400 may be disposed inside the chamber 100 in a way such that the deposition module 400 faces the substrate S. According to an embodiment of the disclosure, where the electrostatic chuck 200 on which the substrate S is seated is placed on the upper side in the chamber 100, the deposition module 400 may be placed on the lower side in the chamber 100. The deposition module 400 may be placed in a way such that the deposition module 400 can move horizontally in the chamber 100. The deposition module 400 may include a rail 410, a main body 420, and a deposition nozzle 430.

The rail 410 may support at least one selected from the main body 420 and the deposition nozzle 430 in a way such that the main body 420 or the deposition nozzle 430 can move horizontally. The rail 410 may extend horizontally inside the chamber 100. There may be a plurality of rails 410, which are spaced apart from each other and extend in the first direction. The first direction may be the back-and-forth direction in FIG. 3. The rail 410 may be disposed on the lower side in the chamber 100.

The main body 420 may be disposed on the rail 410 and may move in the first direction along the rail 410. In other words, the main body 420 may move in the back-and-forth direction of FIG. 3 along the rail 410. The main body 420 may support the deposition nozzle 430. An actuator (not shown) for moving the main body 420 along the rail 410 may be provided on the main body 420, such that the main body 420 can move along the rail 410 by the operation of the actuator.

The deposition nozzle 430 may discharge a deposition material and supply the deposition material to the substrate S. The deposition nozzle 430 may be disposed on the upper surface of the main body 420 and supported by the main body 420. The deposition nozzle 430 may extend in a second direction from the upper surface of the main body 420. The second direction may refer to a direction that is horizontally orthogonal to the first direction and may be the left-to-right direction in FIG. 3. The deposition nozzle 430 may be connected to a deposition material storage (not shown) and may receive the deposition material stored in the deposition material storage to discharge it. The deposition nozzle 430 may discharge the deposition material upward to supply the deposition material to the substrate S.

The deposition module 400 may move to a deposition position when the deposition module 400 discharges the deposition material to the mask assembly 300, and may move to a standby position when the deposition module 400 does not discharge the deposition material to the mask assembly 300. The deposition position may be a position where the deposition module 400 overlaps the mask assembly 300 in a thickness direction of the mask assembly 300, and the standby position may be a position where the deposition module 400 does not overlap the mask assembly 300 in the thickness direction of the mask assembly 300. In an embodiment, for example, the deposition position may be the position where the main body 420 is moved along the rail 410 and is located directly below the mask assembly 300 as shown in FIG. 2, and the standby position may be the position where the main body 420 is moved to the front or rear in the first direction along the rail and is located not directly below the mask assembly 300.

In an embodiment, the connection module 500 may be disposed inside the chamber 100 and may connect the outside of the chamber 100 with the inside of the main body 420. In an embodiment, as shown in FIG. 4, the connection module 500 may include a first fixing member 510, a first rotating member 520, a rotating connection member 530, a second rotating member 540, and a second fixing member 550.

The first fixing member 510 may provide a passage connecting the outside of the chamber 100 with the inside of the chamber 100. The first fixing member 510 may have a hollow cylindrical structure and may be fixed to the lower surface in the chamber 100. The first fixing member 510 may be disposed on the lower surface in the chamber 100 located directly below the mask assembly 300. A through hole is defined or formed on the lower surface in the chamber 100, and the first fixing member 510 may be disposed on the lower surface in the chamber 100 such that the hollow portion of the first fixing member 510 is connected to the through hole of the chamber 100, thereby connecting the outside of the chamber 100 with the inside of the chamber 100.

The first rotating member 520 may be rotatably connected to the upper portion of the first fixing member 510. The first rotating member 520 may be provided as a rectangular block extending in a direction, and a first communication space may be formed therein. The first rotating member 520 may have one side rotatably connected to the first fixing member 510, such that the first communication space therein may be connected to the hollow portion of the first fixing member 510. As the first communication space of the first rotating member 520 is connected to the hollow portion of the first fixing member 510, the first communication space may be connected to the outside of the chamber 100. An observation window 521 may be formed at the upper portion of one side of the first rotating member 520. The observation window 521 can provide the field of view of the camera 600 when the camera 600 captures images of the electrostatic chuck 200 or the mask assembly 300.

The rotating connection member 530 may be rotatably connected to the first rotating member 520. The rotating connection member 530 may have a hollow cylindrical structure, and its lower portion may be rotatably connected to the other side of the first rotating member 520. Since the lower portion of the rotating connection member 530 may be rotatably connected to the other side of the first rotating member 520, and the hollow portion of the rotating connection member 530 may be communicated with the first communication space in the first rotating member 520.

The second rotating member 540 may be rotatably connected to the upper portion of the rotating connection member 530. The second rotating member 540 may be provided as a rectangular block extending in a direction, and a second communication space may be formed therein. The second rotating member 540 may have one side rotatably connected to the upper portion of the rotating connection member 530, such that the second communication space therein may be connected to the hollow portion of the rotating connection member 530. As the second communication space of the second rotating member 540 is connected to the hollow portion of the rotating connection member 530, the second communication space may be connected to the first communication space. The other side of the second rotating member 540 may be rotatably connected to the second fixing member 550.

The second fixing member 550 may provide a passage with the inside of the main body 420. The second fixing member 550 may have a hollow cylindrical structure and may be fixed to the lower face of the main body 420. A through hole is defined or formed in the lower face of the main body 420, and the upper portion of the second fixing member 550 is disposed on the lower face of the main body 420 such that the hollow portion of the second fixing member 550 is connected to the through hole of the main body 420, thereby connecting the inside of the main body 420 with the second fixing member 550. As the lower portion of the second fixing member 550 is rotatably connected to the other side of the second rotating member 540, the hollow portion of the second fixing member 550 may be connected to the second communication space. In other words, the second communication space of the second rotating member 540 may be communicated with the inside of the main body 420 by the second fixing member 550.

The camera 600 may capture images of the electrostatic chuck 200 or the mask assembly 300. The camera 600 may be disposed such that it is located directly below the mask assembly 300 under the deposition module 400. The camera 600 may be disposed inside the connection module 500. For example, the camera 600 may be disposed inside one end of the first rotating member 520. Since the one side of the first rotating member 520 is positioned directly below the mask assembly 300, the camera 600 may be disposed directly below the mask assembly 300. The camera 600 may be disposed inside the one side of the first rotating member 520 in a way such that the lens faces the mask assembly 300. In other words, the lens of the camera 600 may be disposed to face the observation window 521 of the first rotating member 520. The camera 600 may capture images of the electrostatic chuck 200 or the mask assembly 300 when the main body 420 is moved to the standby position. When the main body 420 is moved to the deposition position, the main body 420 is located above the camera 600, and thus the camera 600 may not effectively capture images of the electrostatic chuck 200 or the mask assembly 300. Accordingly, the camera 600 may capture images of the electrostatic chuck 200 or the mask assembly 300 only when the main body 420 is moved to the standby position.

The analysis unit 700 receives and analyzes the images captured by the camera 600, and may determine whether the electrostatic chuck 200 or the mask assembly 300 is normal based on the analysis results. In an embodiment, for example, the analysis unit 700 may store images when the electrostatic chuck 220 and the mask assembly 300 are normal, and the analysis unit 700 may receive the images captured by the camera 600 and compare the images with previously stored images, thereby determining whether the electrostatic chuck 220 and the mask assembly 300 are normal or not. In an embodiment, the analysis unit 700 may include a circuitry configured to perform the operations described above.

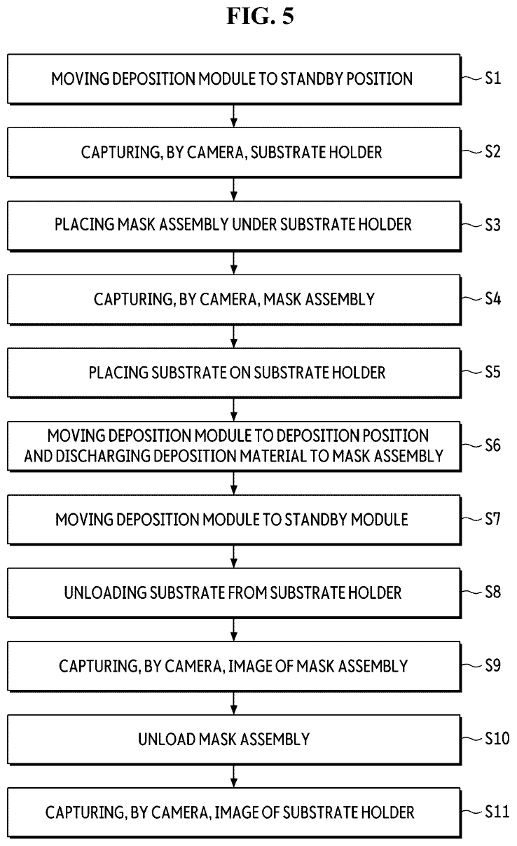

FIG. 5 is a flowchart for illustrating an inspection method by a deposition apparatus 10 according to an embodiment of the disclosure.

Referring to FIG. 5, an inspection method by the deposition apparatus 10 according to an embodiment of the disclosure may include: performing a first deposition standby process (S1), firstly inspecting an electrostatic chuck (S2), placing a mask assembly (S3), firstly inspecting the mask assembly (S4), placing a substrate (S5), performing a deposition process (S6), performing a second deposition standby process (S7), unloading the substrate (S8), secondly inspecting the mask assembly (S9), unloading the mask assembly (S10), and secondly inspecting the electrostatic chuck (S11).

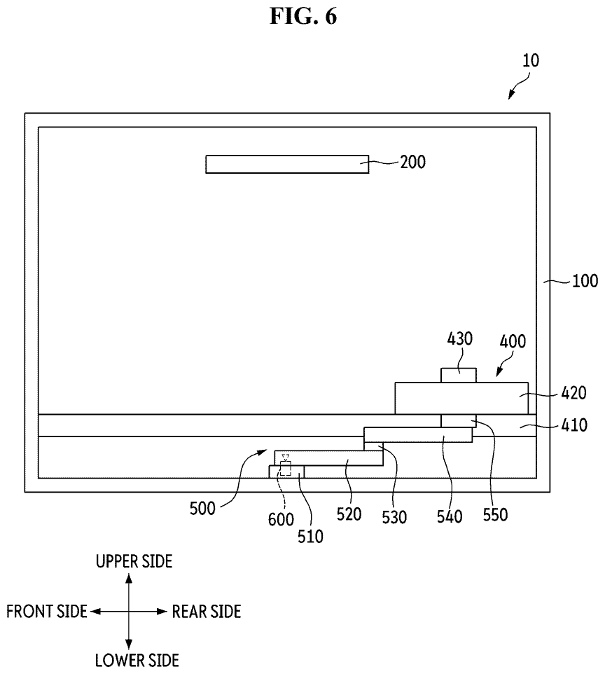

FIG. 6 is a view showing the first deposition standby process S1 and the firstly inspecting an electrostatic chuck S2 of FIG. 5.

Referring to FIG. 6, in the first deposition standby process S1, the deposition module 400 may move to a standby position. In the first deposition standby process S1, the main body 420 of the deposition module 400 may be moved to the rear side along the rail 410 in FIG. 6 such that the main body 420 may be located at the standby position. As the main body 420 moves to the rear side in FIG. 6, the first rotating member 520 and the second rotating member 540 rotate in a way such that the connection module 500 may extend to the rear side as shown in FIG. 6.

In the firstly inspecting an electrostatic chuck S2, the camera 600 may capture an image of the electrostatic chuck 200. Since the main body 420 is moved to the rear in FIG. 6 in the first deposition standby process S1, the main body 420 is not positioned above the camera 600, such that the camera 600 may effectively capture an image of the electrostatic chuck 200 without being blocked by the main body 420. The captured image of the electrostatic chuck 200 captured by the camera 600 may be transmitted to the analysis unit 700. The analysis unit 700 may compare the transmitted captured image of the electrostatic chuck 200 with the previously stored image of the normal electrostatic chuck 200 and analyze the transmitted captured image of the electrostatic chuck 200 to determine whether the electrostatic chuck 200 is normal or not.

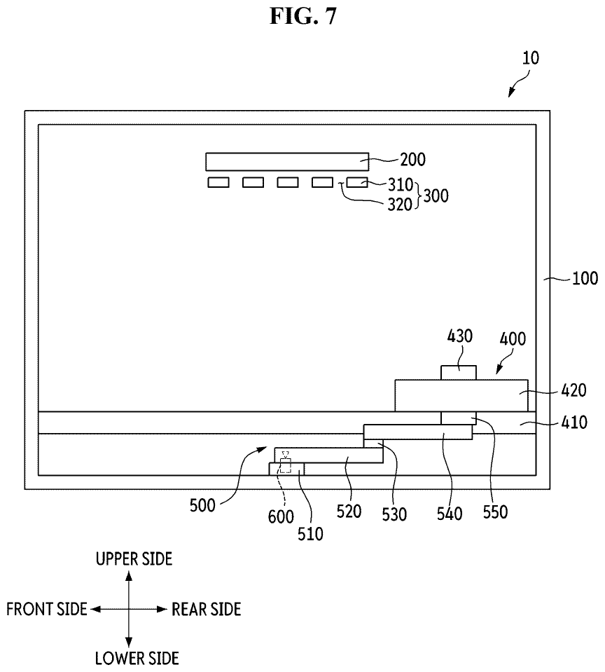

FIG. 7 is a view showing the pacing a mask assembly S3 and the firstly inspecting the mask assembly S4 of FIG. 5.

Referring to FIG. 7, in the placing the mask assembly S3, the mask assembly 300 may be placed under the electrostatic chuck 200. In the placing the mask assembly S3, the mask assembly 300 may be placed under the electrostatic chuck 200 at a certain distance from the electrostatic chuck 200. The mask assembly 300 may be fixed to a predetermined position or location under the electrostatic chuck 200 by a fixing member of the electrostatic chuck 200.

In the firstly inspecting the mask assembly S4, the camera 600 may capture an image of the mask assembly 300. Since the main body 420 is moved to the rear in FIG. 7 in the first deposition standby S1, the main body 420 is not positioned above the camera 600, to allow the camera 600 to capture an image of the mask assembly 300. The captured image of the mask assembly 300 captured by the camera 600 may be transmitted to the analysis unit 700. The analysis unit 700 may compare the transmitted captured image of the mask assembly 300 with the previously stored image of the normal mask assembly 300 and analyze the transmitted captured image of the mask assembly 300 to determine whether the mask assembly 300 is normal or not.

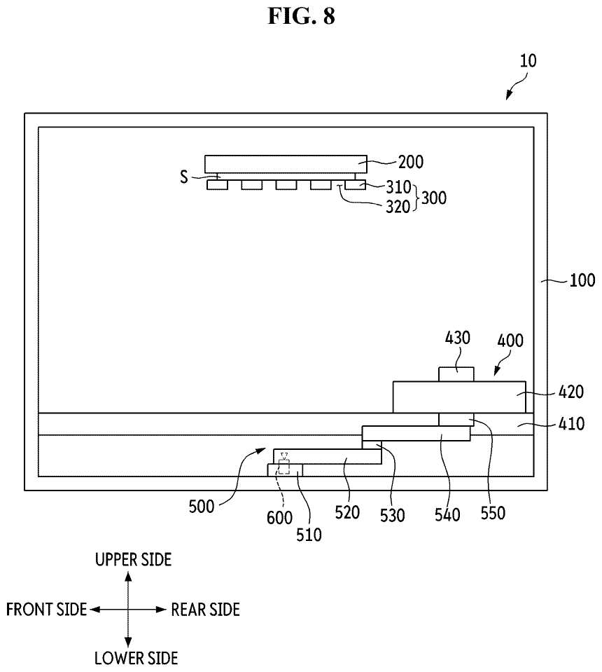

FIG. 8 is a view showing the placing the substrate S5 of FIG. 5.

Referring to FIG. 8, in the placing the substrate S5, the substrate S may be disposed on the electrostatic chuck 200. In the placing the substrate S5, the substrate S may be placed under the electrostatic chuck 200 and on the mask assembly 300. In other words, in the placing the substrate S5, the substrate S may be placed between the electrostatic chuck 200 and the mask assembly 300.

After the substrate S is placed on the electrostatic chuck 200, the camera 600 may further capture the substrate S and the mask assembly 300. The captured images of the substrate S and the mask assembly 300 captured by the camera 600 may be to the analysis unit 700, and the analysis unit 700 may analyze the transmitted images to determine whether the substrate is correctly placed on the electrostatic chuck. In addition, the analysis unit 700 may analyze the transmitted images to determine whether the substrate S and the mask assembly 300 are correctly aligned.

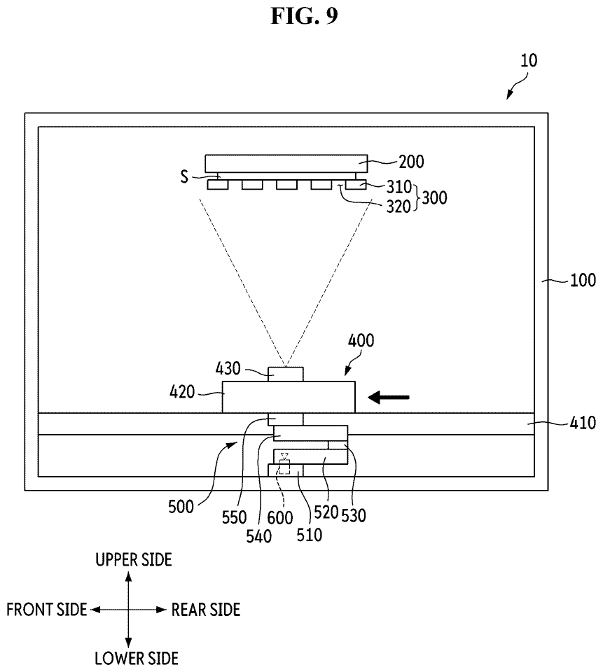

FIG. 9 is a view showing the deposition process S6 of FIG. 5.

Referring to FIG. 9, in performing the deposition process S6, the deposition module 400 may be moved to a deposition position and a deposition material may be discharged. In the deposition S+, the main body 420 of the deposition module 400 may be moved to the front along the rail 410 in FIG. 9 such that the main body 420 may be located directly below the mask assembly 300. As the main body 420 moves to the front in FIG. 9, the first rotating member 520 and the second rotating member 540 may rotate in a way such that the first rotating member 520 and the second rotating member 540 may overlap each other. In other words, the overall length of the connection module 500 can be reduced as the first rotating member 520 and the second rotating member 540 overlap each other. Once the main body 420 is moved to the deposition position, the deposition material may be discharged toward the mask assembly 300 through the deposition nozzle 430. The deposition material discharged to the mask assembly 300 may pass through the transmissive portions 320 to be deposited on the substrate S.

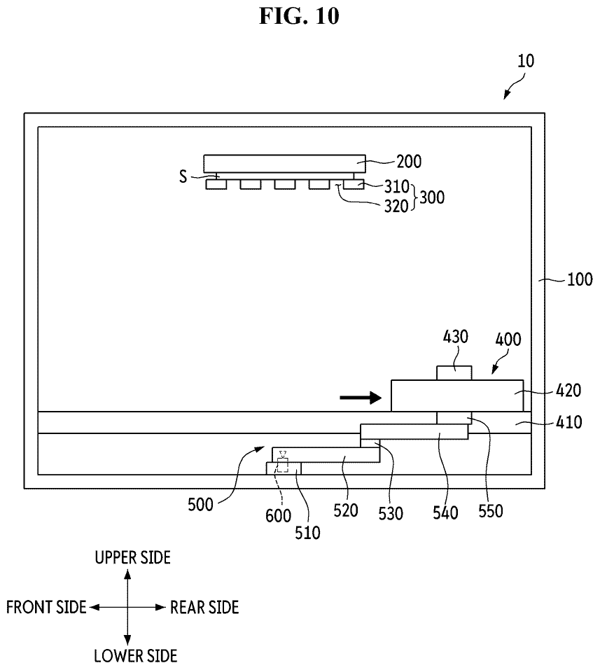

FIG. 10 is a view showing the second deposition standby process S7 of FIG. 5.

Referring to FIG. 10, in the second deposition standby process S7, the deposition module 400 may move to the standby position again. In the second deposition standby process S7, the main body 420 of the deposition module 400 may be moved to the rear side along the rail 410 in FIG. 10 such that the main body 420 may be located at the standby position. As the main body 420 moves to the rear side in FIG. 10, the first rotating member 520 and the second rotating member 540 rotate in a way such that the connection module 500 may extend to the rear side as shown in FIG. 10.

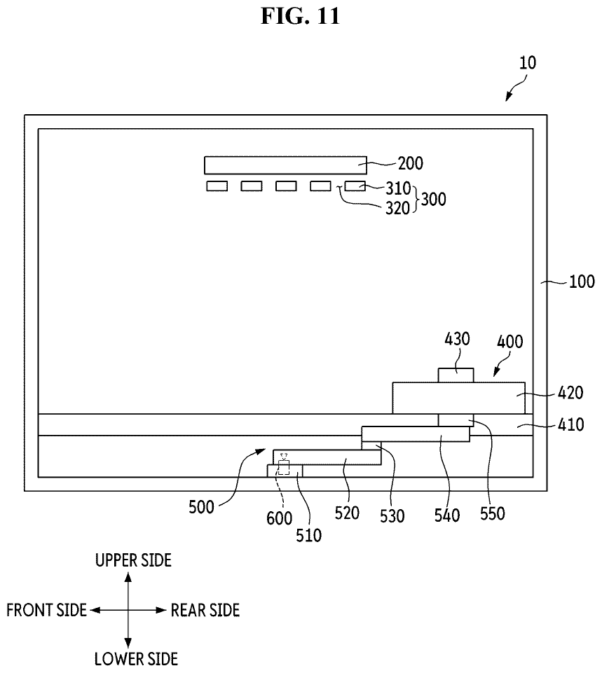

FIG. 11 is a view showing the unloading the substrate S8 and the secondly inspecting a mask assembly S9 of FIG. 5.

Referring to FIG. 11, in the unloading the substrate S8, the substrate S may be unloaded from the electrostatic chuck 200. In the unloading the substrate S8, the substrate S disposed between the electrostatic chuck 200 and the mask assembly 300 may be taken out to the outside of the chamber 100.

In the secondly inspecting the mask assembly S9, the camera 600 may capture an image of the mask assembly 300 again. Since the main body 420 is moved to the rear in FIG. 11 in the second deposition standby process S7, the main body 420 is not positioned above the camera 600, to allow the camera 600 to capture an image of the mask assembly 300. The captured image of the mask assembly 300 captured by the camera 600 again may be transmitted to the analysis unit 700. The analysis unit 700 may compare the transmitted captured image of the mask assembly 300 with the previously stored image of the normal mask assembly 300 and analyze the transmitted captured image of the mask assembly 300 to determine again whether the mask assembly 300 is normal or not. In addition, the analysis unit 700 may analyze the transmitted images to determine whether the substrate S is unloaded properly from the electrostatic chuck 200.

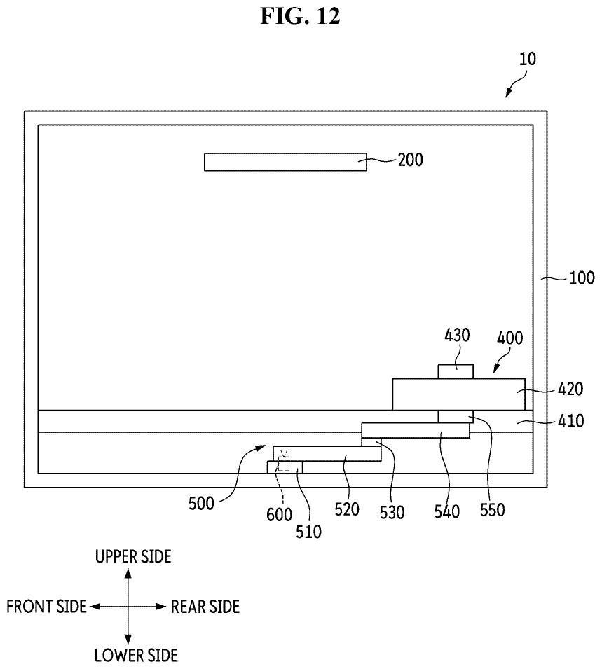

FIG. 12 is a view showing the unloading the mask assembly S10 and the secondly inspecting the electrostatic chuck S11 of FIG. 5.

Referring to FIG. 12, in the unloading the mask assembly S10, the mask assembly 300 may be unloaded. In the unloading the mask assembly S10, the mask assembly 300 placed under the electrostatic chuck 200 may be taken out of the outside of the chamber 100.

In the secondly inspecting the electrostatic chuck S11, the camera 600 may capture the electrostatic chuck 200 again. Since the main body 420 is moved to the rear in FIG. 12 in the second deposition standby process S7, the main body 420 is not positioned above the camera 600, to allow the camera 600 to capture an image of the electrostatic chuck 200. The captured image of the electrostatic chuck 200 captured again by the camera 600 may be transmitted to the analysis unit 700. The analysis unit 700 may compare the transmitted captured image of the electrostatic chuck 200 with the previously stored image of the normal electrostatic chuck 200 and analyze the transmitted captured image of the electrostatic chuck 200 to determine again whether the electrostatic chuck 200 is normal or not.

The display device according to one embodiment of the present disclosure can be applied to various electronic devices. The electronic device according to the one embodiment of the present disclosure includes the display device described above, and may further include modules or devices having additional functions in addition to the display device.

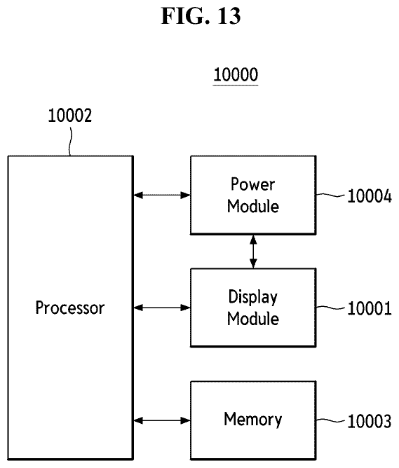

FIG. 13 is a block diagram of an electronic device according to one embodiment of the present disclosure.

Referring to FIG. 13, the electronic device 10000 according to one embodiment of the present disclosure may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

The memory 10003 may store data information necessary for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to the one embodiment of the present disclosure may be included in the display device according to the embodiments of the present disclosure. In addition, some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

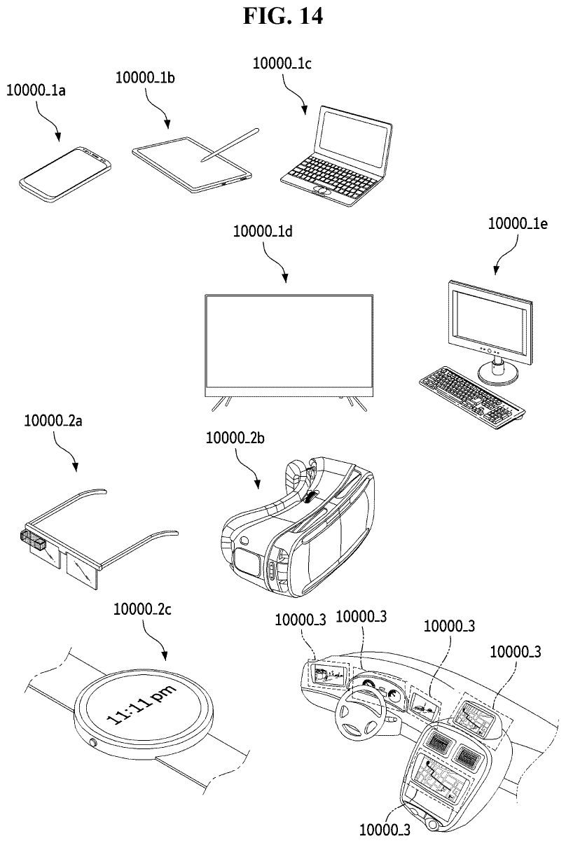

FIG. 14 is a schematic diagram of an electronic device according to various embodiments of the present disclosure.

Referring to FIG. 14, various electronic devices to which display devices according to embodiments of the present disclosure are applied may include not only image display electronic devices such as a smart phone 10000_1a, a tablet PC (personal computer) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a CID (Center Information Display) and a room mirror display arranged on a dashboard, center fascia, and dashboard of an automobile.

According to embodiments of the disclosure, as described herein, it is possible to inspect, by a deposition apparatus, whether an electrostatic chuck and a mask assembly inside a chamber is normal or not, thereby effectively preventing failure in a process of depositing a deposition material onto a substrate.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition apparatus comprising:
an electrostatic chuck which supports a substrate;
a mask assembly disposed on a surface of the substrate;
a deposition module disposed to be movable in a horizontal direction intersecting a thickness direction of the mask assembly, wherein the deposition module discharges a deposition material to the mask assembly; and
a camera which captures an image of the electrostatic chuck or the mask assembly,
wherein the deposition module is in a deposition position overlapping the mask assembly in the thickness direction of the mask assembly while the deposition module discharges the deposition material, and is in a standby position not overlapping the mask assembly in the thickness direction of the mask assembly while the deposition module does not discharge the deposition material, and
wherein the camera captures the image of the electrostatic chuck or the mask assembly when the deposition module is in the standby position.

2. The deposition apparatus of claim 1, wherein the camera overlaps the deposition module in the thickness direction of the mask assembly when the deposition module is in the deposition position, and does not overlap the deposition module in the thickness direction of the mask assembly when the deposition module is in the standby position.

3. The deposition apparatus of claim 2, wherein the camera under the deposition module is disposed below the mask assembly to overlap the mask assembly in the thickness direction.

4. The deposition apparatus of claim 2, further comprising:
a chamber which accommodates the electrostatic chuck, the mask assembly, the deposition module and the camera; and
a connection module disposed inside the chamber, wherein the connection module connects an outside of the chamber with an inside of the deposition module.

5. The deposition apparatus of claim 4, wherein the camera is disposed inside the connection module.

6. The deposition apparatus of claim 5, wherein the connection module comprises:
a first fixing member disposed on an inner surface of the chamber located below the mask assembly, wherein the first fixing member provides a passage to the outside of the chamber;
a first rotating member with one end rotatably connected to the first fixing member, wherein a first communication space is defined in the first rotating member to communicate with the outside of the chamber;
a second fixing member disposed on the deposition module, wherein the second fixing member provides a passage to the inside of the deposition module; and
a second rotating member with one end rotatably connected to an opposite end of the first rotating member and an opposite end rotatably connected to the second fixing member, wherein a second communication space is defined in the second rotating member to communicate with the first communication space and the inside of the deposition module.

7. The deposition apparatus of claim 6, wherein the connection module further comprises a rotating connection member which rotatably connects the opposite end of the first rotating member with the one end of the second rotating member.

8. The deposition apparatus of claim 6, wherein the camera is disposed inside the one end of the first rotating member.

9. The deposition apparatus of claim 8, wherein the camera is disposed in a way such that a lens thereof faces the mask assembly, and an observation window is disposed on an upper side of the one end of the first rotating member.

10. The deposition apparatus of claim 1, wherein the deposition module comprises:
a rail extending in the horizontal direction; a main body disposed to be movable along the rail;
and a deposition nozzle disposed on the main body to discharge the deposition material to the mask assembly.

11. The deposition apparatus of claim 1, further comprising:
an analysis unit which analyzes the image captured by the camera to determine whether the electrostatic chuck or the mask assembly is normal or not.

12. An inspection method by a deposition apparatus, the method comprising:
moving a deposition module to a standby position;
firstly capturing, by a camera, an image of an electrostatic chuck;
placing a mask assembly under the electrostatic chuck; and
firstly capturing, by the camera, an image of the mask assembly.

13. The method of claim 12, wherein the deposition module does not overlap the electrostatic chuck or the mask assembly in a thickness direction of the electrostatic chuck or the mask assembly when the deposition module is in the standby position.

14. The method of claim 13, wherein the camera is disposed below the electrostatic chuck or the mask assembly to overlap the electrostatic chuck or the mask assembly.

15. The method of claim 12, further comprising: after the firstly capturing, by the camera, the image of the mask assembly,
placing a substrate on the electrostatic chuck.

16. The method of claim 15, further comprising: after the placing the substrate on the electrostatic chuck,
moving the deposition module to a deposition position and discharging a deposition material to the mask assembly.

17. The method of claim 16, wherein the deposition module overlaps the electrostatic chuck or the mask assembly in a thickness direction of the electrostatic chuck or the mask assembly when the deposition module is in the deposition position.

18. The method of claim 16, further comprising: after the discharging the deposition material to the mask assembly,
moving the deposition module to the standby position.

19. The method of claim 18, further comprising: after the moving the deposition module to the standby position,
unloading the substrate from the electrostatic chuck; and
secondly capturing, by the camera, an image of the mask assembly,
after the secondly capturing, by the camera, the image of the mask assembly,
unloading the mask assembly; and
secondly capturing, by the camera, an image of the electrostatic chuck.

20. An electronic device comprising:
a display device manufactured by a deposition apparatus;
the deposition apparatus comprising:
an electrostatic chuck which supports a substrate;
a mask assembly disposed on a surface of the substrate;
a deposition module disposed to be movable in a horizontal direction intersecting a thickness direction of the mask assembly, wherein the deposition module discharges a deposition material to the mask assembly; and
a camera which captures an image of the electrostatic chuck or the mask assembly,
wherein the deposition module is in a deposition position overlapping the mask assembly in the thickness direction of the mask assembly while the deposition module discharges the deposition material, and is in a standby position not overlapping the mask assembly in the thickness direction of the mask assembly while the deposition module does not discharge the deposition material, and
wherein the camera captures the image of the electrostatic chuck or the mask assembly when the deposition module is in the standby position.
